(19) United States
(12) Patent Application Publication
(10) Pub. No.: US 2026/0040889 A1
(43) Pub. Date: Feb. 5, 2026

(54) WAFER POSITIONING RING DEVICE

(71) Applicant: PASCO PRECISION CORP., Tainan City (TW)

(72) Inventor: Chih-Ching LIN, Tainan City (TW)

(21) Appl. No.: 19/212,282

(22) Filed: May 19, 2025

(30) Foreign Application Priority Data
Aug. 1, 2024 (TW) 113128814
Dec. 20, 2024 (TW) 113149945

(51) Int. Cl. H01L 21/687; H01L 21/67; H01L 21/68

(52) U.S. Cl. CPC H01L 21/68721; H01L 21/67092; H01L 21/68; H01L 21/6875

(57) ABSTRACT

A wafer positioning ring device includes a polishing ring that has a polishing ring inner surface surrounded by a polishing ring outer surface, a connecting ring that has a connecting ring inner surface surrounded by a connecting ring outer surface, and a positioning unit. The positioning unit includes first positioning members that are disposed on one of the polishing ring outer surface of the polishing ring and the connecting ring inner surface of the connecting ring, and second positioning members that are disposed on another one of the polishing ring outer surface of the polishing ring and the connecting ring inner surface of the connecting ring. The second positioning members and the first positioning members are detachably and respectively connected to each other such that the connecting ring is positioned to the polishing ring.

### CROSS-REFERENCE TO RELATED APPLICATION

This application claims priority to Taiwanese Invention patent application No. 113128814, filed on Aug. 1, 2024, and Taiwanese Invention patent application No. 113149945, filed on Dec. 20, 2024, the entire disclosure of which is incorporated by reference herein.

### FIELD

The disclosure relates to a positioning ring device, and more particularly to a wafer positioning ring device.

### BACKGROUND

Referring to FIGS. 1, 2, and 3, a conventional wafer positioning ring device includes a polishing ring 1, a connecting ring 2 stacked on a top surface of the polishing ring 1, and a plurality of fasteners 3 fixed to a bottom surface of the connecting ring 2. The top surface of the polishing ring 1 is formed with a plurality of circumferentially spaced-apart connecting holes 11 that are respectively engageable with the fasteners 3. Each of the connecting holes 11 has a through hole portion 12 and a restricting hole portion 13 that is in communication with the through hole portion 12 and that extends circumferentially. Each of the fasteners 3 has a fastener body portion 31 that is fastened to the bottom surface of the connecting ring 2, and a fastener head portion 32 that extends transversely from the fastened body portion 31 and that has a width greater than a width of the fastener head portion 31.

To fix the connecting ring 2 to the polishing ring 1, the fasteners 3 are first fastened to the connecting ring 2. Subsequently, the fasteners 3 are respectively aligned with the connecting holes 11 such that the fastener head portions 32 of the fasteners 3 respectively extend through the through hole portions 12 of the connecting holes 11. By rotating the connection ring 2 relative to the polishing ring 1, the fastener head portions 32 of the fasteners 3 are driven to be respectively engaged with the restricting hole portions 13 of the connecting holes 11 of the polishing ring 1. As a result, the fastener head portions 32 of the fasteners 3 that are respectively engaged with the restricting hole portions 13 of the connecting holes 11 may prevent the connection ring 2 from being detached from the polishing ring 1, thereby completing assembly of the conventional wafer positioning ring device. However, because the fasteners 3 must first be fixed to the connection ring 2, and then must be respectively aligned with the connecting holes 11, the assembly of the conventional wafer positioning ring device is not easy and is time-consuming.

### SUMMARY

Therefore, an object of the disclosure is to provide a wafer positioning ring device that can alleviate at least one of the drawbacks of the prior art.

According to the disclosure, the wafer positioning ring device includes a polishing ring, a connecting ring, and a positioning unit.

The polishing ring has a polishing ring inner surface and a polishing ring outer surface that surrounds the polishing ring inner surface.

The connecting ring has a connecting ring inner surface and a connecting ring outer surface that surrounds the connecting ring inner surface.

The positioning unit includes a plurality of first positioning members and a plurality of second positioning members. The first positioning members are spaced apart from each other and are disposed on one of the polishing ring outer surface of the polishing ring and the connecting ring inner surface of the connecting ring. The second positioning members are spaced apart from each other and are disposed on another one of the polishing ring outer surface of the polishing ring and the connecting ring inner surface of the connecting ring.

The second positioning members and the first positioning members are detachably and respectively connected to each other such that the connecting ring is positioned on top of the polishing ring.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is an exploded perspective view illustrating a conventional wafer positioning ring device.

FIG. 2 is a fragmentary enlarged view of FIG. 1.

FIG. 3 is a fragmentary enlarged section view of the conventional wafer positioning ring device.

FIG. 4 is a perspective view illustrating a wafer positioning ring device according to a first embodiment of the disclosure.

FIG. 5 is a perspective view of the first embodiment illustrating the wafer positioning ring device from another angle of view.

FIG. 6 is an exploded perspective view of the first embodiment illustrating the wafer positioning ring device.

FIG. 7 is a fragmentary schematic perspective view of the first embodiment illustrating a second positioning member disposed on a connecting ring inner surface of a connecting ring of the wafer positioning ring device.

FIG. 8 is a fragmentary schematic perspective view of the first embodiment illustrating a first positioning member disposed on a polishing ring outer surface of a polishing ring of the wafer positioning ring device.

FIG. 9 is a fragmentary schematic section view of the first embodiment illustrating how the second positioning member and the first positioning member are connected to each other such that the connecting ring is positioned on the polishing ring.

FIG. 10 is a fragmentary schematic sectional view of the first embodiment illustrating the connecting ring positioned on the polishing ring.

FIG. 11 is a fragmentary schematic perspective view illustrating a wafer positioning ring device according to a second embodiment of the disclosure.

FIG. 12 is a fragmentary schematic section view of the second embodiment illustrating how the second positioning member and the first positioning member are connected to each other such that the connecting ring is positioned on the polishing ring.

FIG. 13 is an exploded perspective view illustrating a wafer positioning ring device according to a third embodiment of the disclosure.

FIG. 14 is a fragmentary schematic perspective view of the third embodiment illustrating the second positioning member indented from the polishing ring outer surface of the polishing ring.

FIG. 15 is a fragmentary schematic perspective view of the third embodiment illustrating the first positioning member integrally formed on the connecting ring.

FIG. 16 is a fragmentary schematic section view of the third embodiment illustrating how the second positioning member and the first positioning member are connected to each other such that the connecting ring is positioned on the polishing ring.

FIG. 17 is a fragmentary schematic sectional view of the third embodiment illustrating the connecting ring positioned on the polishing ring.

FIG. 18 is a fragmentary schematic perspective view illustrating a wafer positioning ring device according to a third embodiment of the disclosure, the first positioning member not integrally formed on the connecting ring.

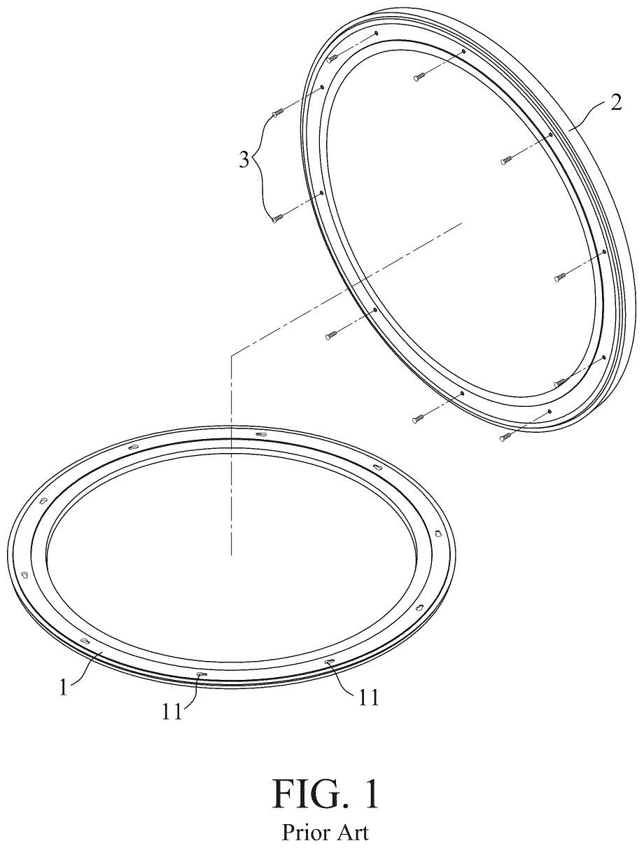

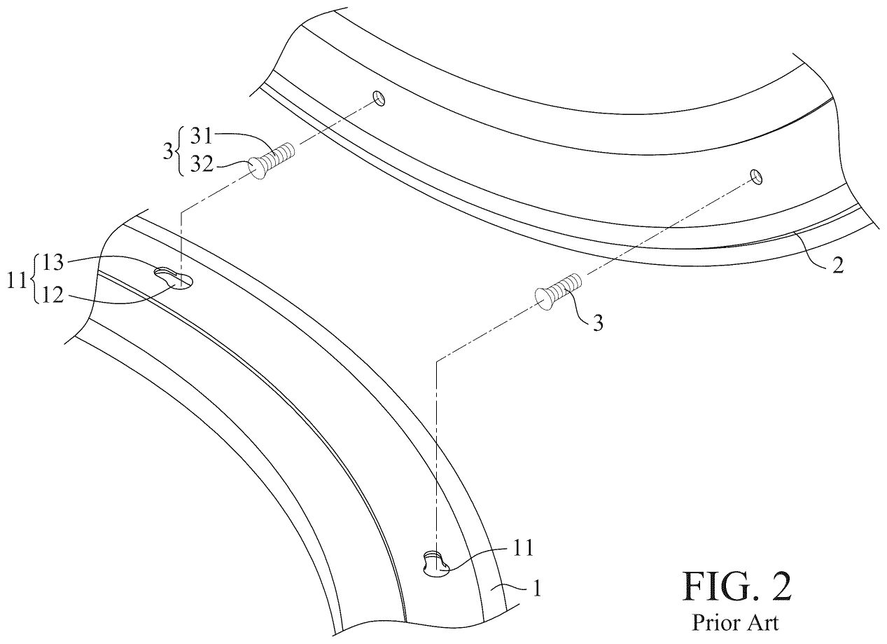

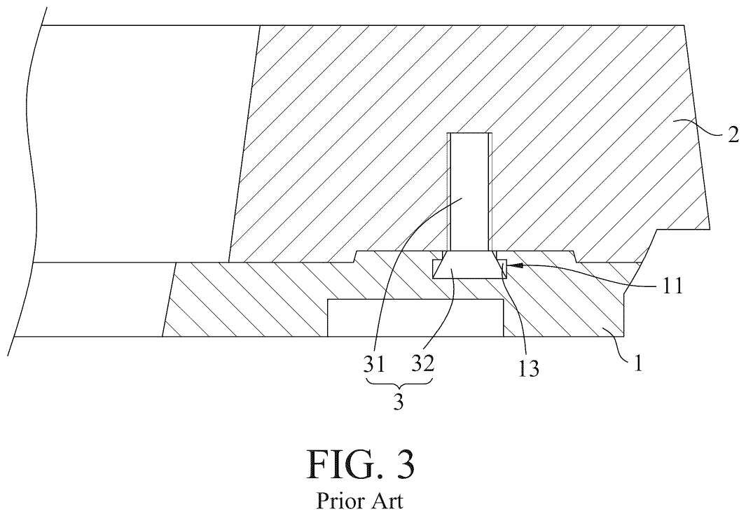

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

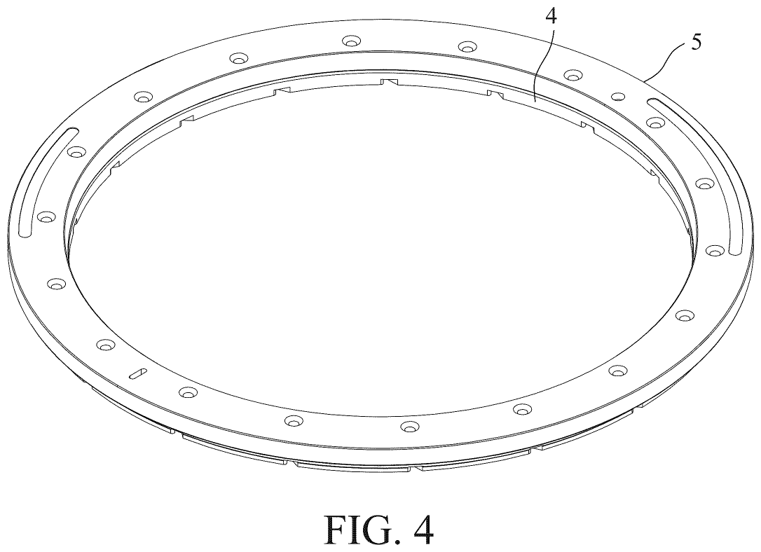

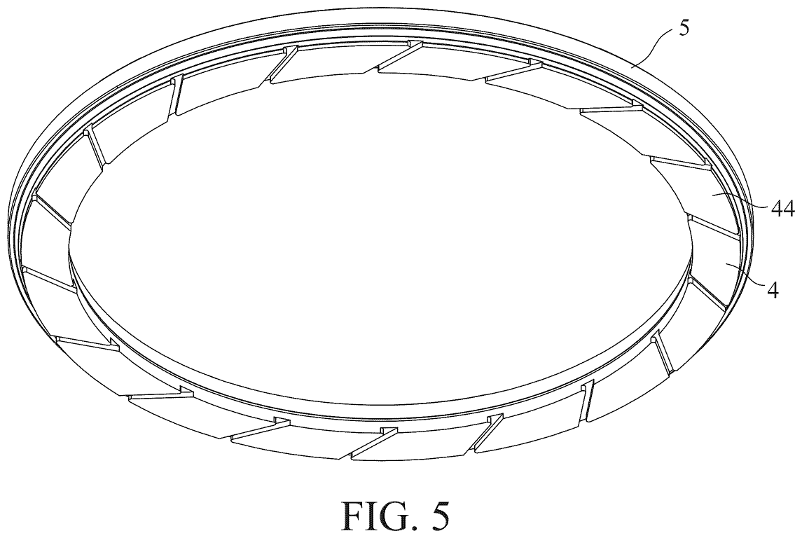

Referring to FIGS. 4, 5, and 6, a wafer positioning ring device according to a first embodiment of the disclosure is adapted to be mounted on a polishing head (not shown) and to position a wafer (not shown) for carrying out chemical mechanical polishing (CMP) processes. The wafer positioning ring device includes a polishing ring 4, a connecting ring 5, and a positioning unit 6.

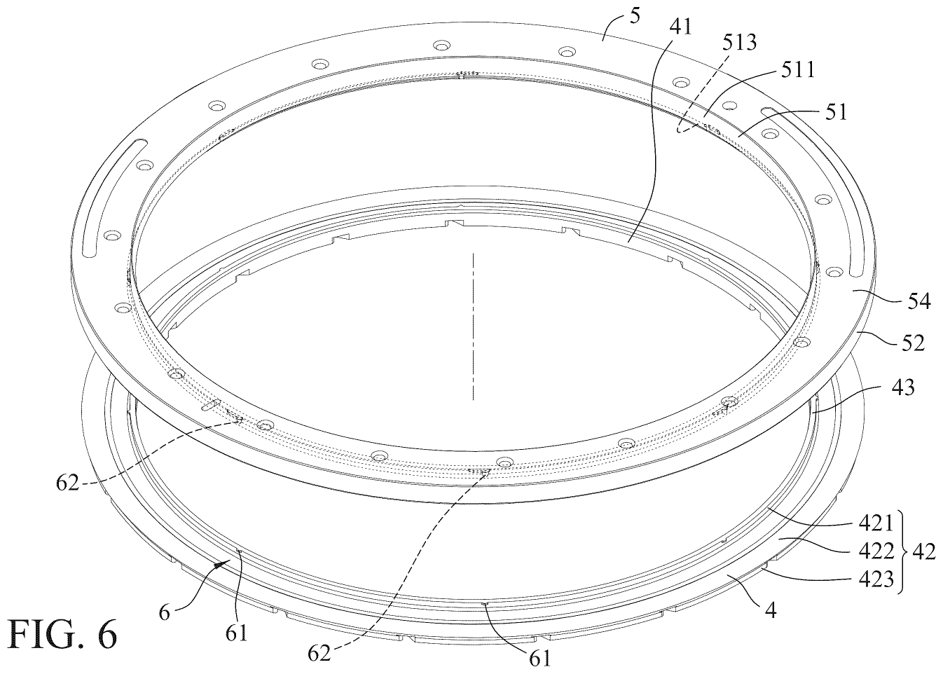

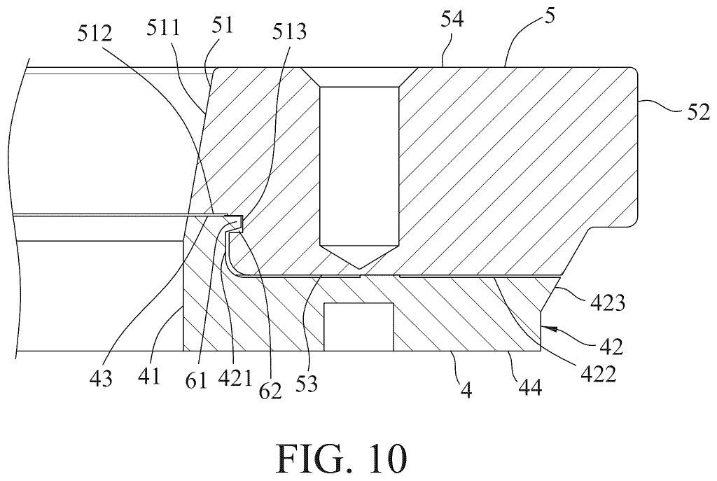

Referring to FIGS. 6, 8, and 10, the polishing ring 4 is adapted to position the wafer (not shown) and has a circular ring shape. In this embodiment, the polishing ring 4 has a polishing ring inner surface 41, a polishing ring outer surface 42 that surrounds the polishing ring inner surface 41, a polishing ring top surface 43 that faces upwardly and that interconnects the polishing ring inner surface 41 and the polishing ring outer surface 42, and a polishing ring bottom surface 44 that faces downwardly and that interconnects the polishing ring inner surface 41 and the polishing ring outer surface 42.

The polishing ring outer surface 42 has a polishing ring installation portion 421 that extends downwardly from the polishing ring top surface 43, a polishing ring transverse portion 422 that extends radially and outwardly from an end of the polishing ring installation portion 421, and a polishing ring outer peripheral portion 423 that extends downwardly from an end of the polishing ring transverse portion 422 and that is connected to the polishing ring bottom surface 44.

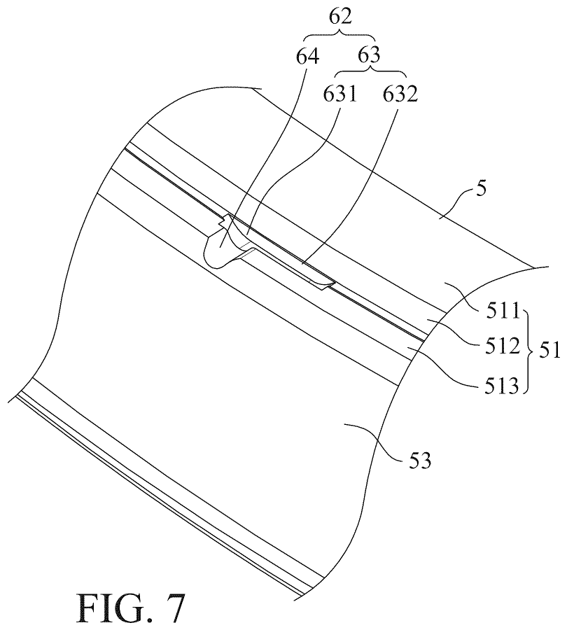

Referring to FIGS. 6, 7, and 10, the connecting ring 5 has a circular ring shape. In this embodiment, the connecting ring 5 has a connecting ring inner surface 51, a connecting ring outer surface 52 that surrounds the connecting ring inner surface 51, a connecting ring bottom surface 53 that faces downwardly the polishing ring transverse portion 422 and that interconnects the connecting ring inner surface 51 and the connecting ring outer surface 52, and a connecting ring top surface 54 that faces upwardly and that interconnects the connecting ring inner surface 51 and the connecting ring outer surface 52.

The connecting ring inner surface 51 has a connecting ring inner peripheral portion 511 that extends downwardly from the connecting ring top surface 54, a connecting ring transverse portion 512 that extends radially and outwardly from an end of the connecting ring inner peripheral portion 511 and that faces the polishing ring top surface 43, and a connecting ring installation portion 513 that extends downwardly from an end of the connecting ring transverse portion 512 and that is connected to the connecting ring bottom surface 53. The connecting ring installation portion 513 faces the polishing ring installation portion 421.

The positioning unit 6 includes a plurality of first positioning members 61 and a plurality of second positioning members 62. The second positioning members 62 and the first positioning members 61 are detachably and respectively connected to each other such that the connecting ring 5 is positioned on top of the polishing ring 4.

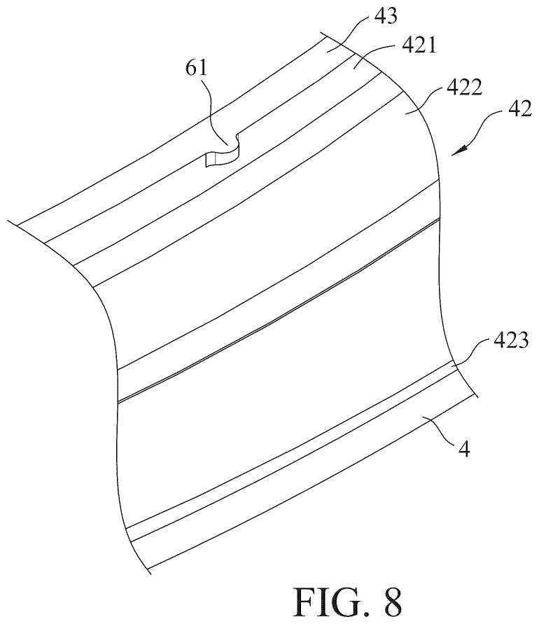

Referring to FIGS. 6 and 8, the first positioning members 61 are equiangularly spaced apart from each other and are disposed on the polishing ring outer surface 42 of the polishing ring 4. Each of the first positioning members 61 is a semi-circular protrusion that extends radially and outwardly from the polishing ring installation portion 421 of polishing ring outer surface 42. In this embodiment, each of the first positioning members 61 is integrally formed on the polishing ring 4.

The second positioning members 62 are equiangularly spaced apart from each other and are disposed on the connecting ring inner surface 51 of the connecting ring 5. Each of the second positioning members 62 is a slot and is indented from the connecting ring installation portion 513 of the connecting ring inner surface 51. Each of the second positioning members 62 is an integral part of the connecting ring 5. In this embodiment, each of the second positioning member 62 has a sliding slot portion 63 and an entry slot portion 64. The sliding slot portion 63 is indented from the connecting ring installation portion 513, extends circumferentially along the connecting ring installation portion 513, and has an arcuate cross-section. The entry slot portion 64 is indented from the connecting ring installation portion 513, is in communication with the sliding slot portion 63, extends through the connecting ring bottom surface 53, and has a semi-circular cross-section.

The sliding slot portion 63 of each of the second positioning members 62 has a sliding region 631 and a restricting region 632. The sliding region 631 is aligned with the entry slot portion 64 and allows a respective one of the first positioning members 61 to be inserted therein. The restricting region 632 is in communication with the sliding region 631, is not aligned with the entry slot portion 64, and retains the respective one of the first positioning members 61 when the connecting ring 5 is rotated relative to the polishing ring 4 after the respective one of the first positioning members 61 is inserted into the sliding region 631, thereby positioning the connecting ring 5 on the top of the polishing ring 4.

Specifically, the polishing ring 4 and the first positioning members 61 are made in one piece of an engineering plastic such as, but not limited to, polyphenylene sulfide (PPS) and polyether ether ketone (PEEK). The connecting ring 5 is made of a metal material such as, but not limited to, stainless steel.

Referring to FIGS. 6, 9, and 10, to assemble the wafer positioning ring device of the disclosure, a region between the connecting ring bottom surface 53 and the connecting ring inner surface 51 of the connecting ring 5 is first abutted against the first positioning members 61. Sequentially, the connecting ring 5 is slightly rotated relative to the polishing ring 4 and is slightly pushed toward the polishing ring 4. When the second positioning members 62 are moved respectively above the first positioning members 61, each of the first positioning members 61 is inserted into the sliding slot portion 63 through the entry slot portion 64 of a respective one of the second positioning members 62 on the connecting ring 5. In a case where the second positioning members 62 are respectively in misalignment with the first positioning members 61 at the start of the assembling process of the wafer positioning ring device, a slight rotation of the connecting ring 5 relative to the polishing ring 4 may facilitate insertion of the first positioning members 61 into the second positioning members 62, respectively. Meanwhile, the connecting ring 5 is stacked on the polishing ring 4.

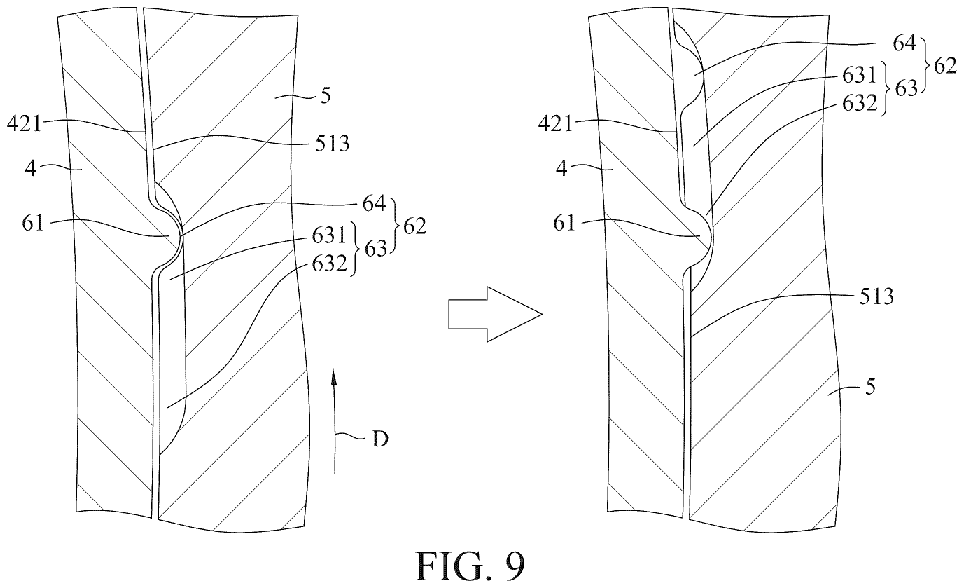

Referring to FIG. 9, the connecting ring 5 is rotated relative to the polishing ring 4 along a rotational direction (D) such that each of the first positioning members 61 is inserted into the restricting region 632 from the sliding region 631 of the sliding slot portion 63 of the respective one of the second positioning members 62. As a result, the first positioning members 61 are respectively positioned and connected to the second positioning members 62 such that the connecting ring 5 is positioned on the top of the polishing ring 4.

Notably, because each of the first positioning members 61 is the semi-circular protrusion, during relative movement between each of the first positioning members 61 and the respective one of the second positioning members 62, friction between each of the first positioning members 61 and the respective one of the second positioning members 62 is reduced such that the connecting ring may be smoothly rotated relative to the polishing ring 4.

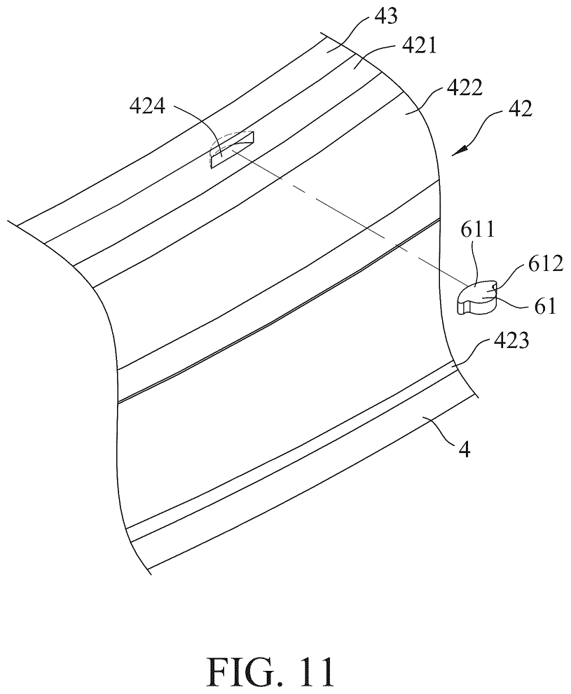

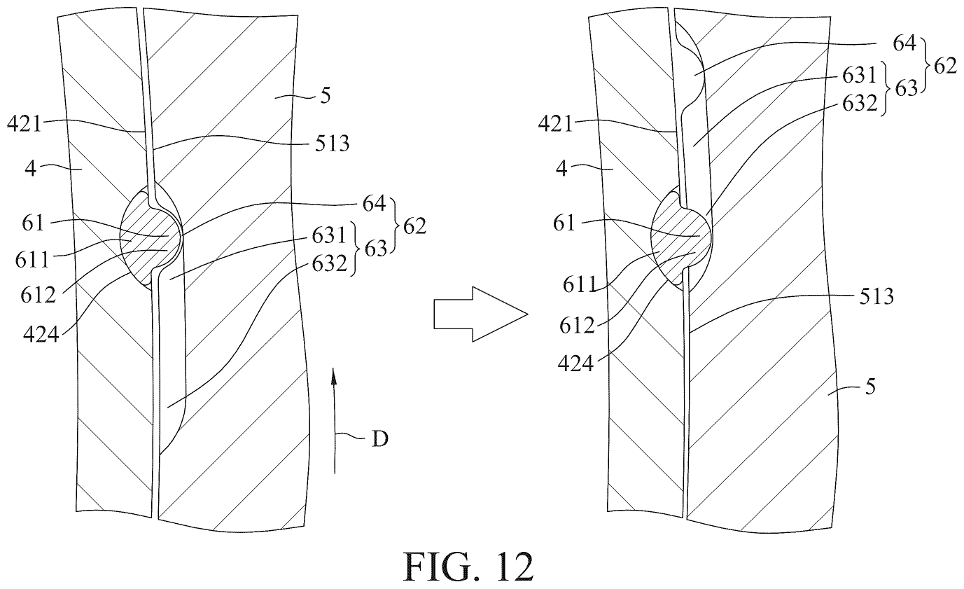

FIGS. 11 and 12 illustrate a wafer positioning ring device according to a second embodiment of the disclosure, which has a structure substantially similar to that of the first embodiment. However, in the second embodiment, the first positioning members 61 are not integrally formed on the polishing ring 4. For brevity, only the differences between the embodiments will be described hereinafter.

In the second embodiment, the polishing ring outer surface 42 has a plurality of installing recesses 424 that are equiangularly spaced apart from each other, that extend circumferentially along the polishing ring outer surface 42, and that are indented from the polishing ring installation portion 421 of the polishing ring outer surface 42. Each of the first positioning members 61 has an arcuate installation segment 611 and an engagement segment 612 that projects outwardly and is arcuately tapered from the arcuate installation segment 611. The arcuate installation segment 611 of each of the first positioning members 61 engages with a respective one of the installing recesses 424. The engagement segment 612 of each of the first positioning members 61 is allowed to engage with the respective one of the second positioning members 62.

To assemble the wafer positioning ring device of the disclosure, the first positioning members 61 are first respectively engaged with the installing recesses 424 of the polishing ring outer surface 42 such that the connecting ring 5 abuts against the top of the polishing ring 4. Sequentially, the connecting ring 5 is positioned on the top of the polishing ring 4 in the manner described in the first embodiment.

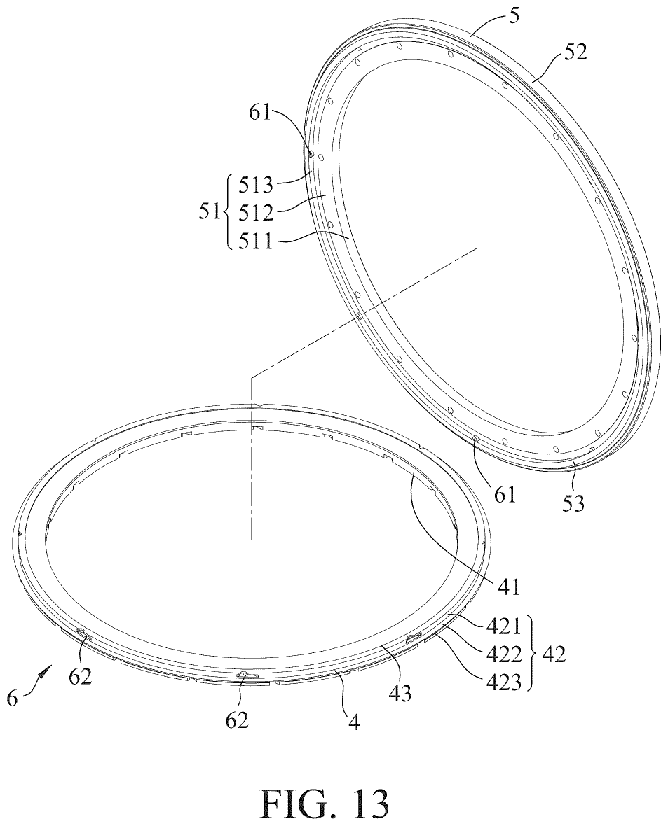

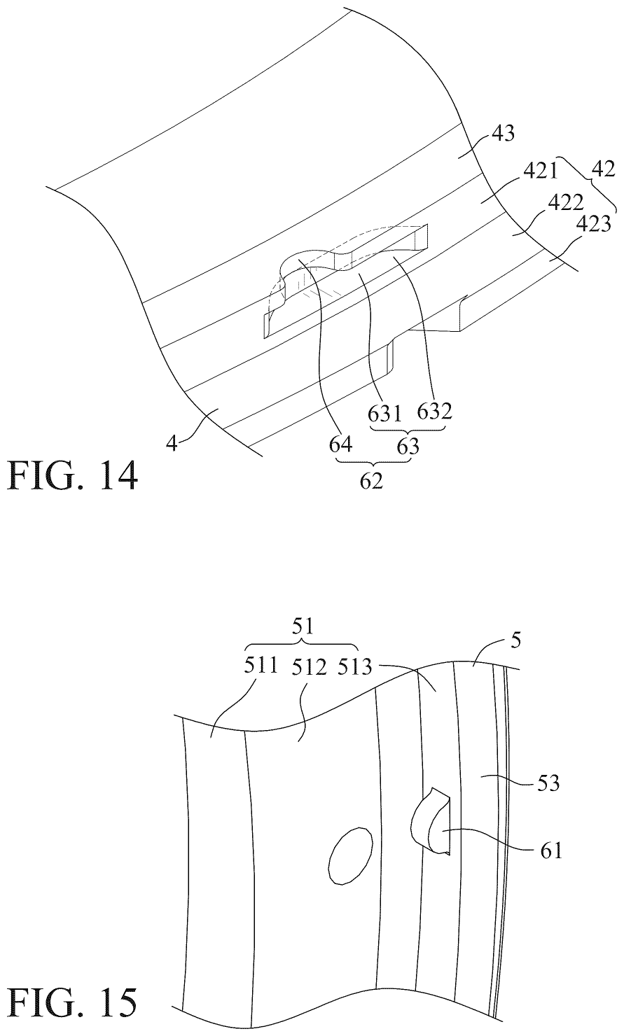

FIGS. 13, 14, and 15 illustrate a wafer positioning ring device according to a third embodiment of the disclosure, which has a structure substantially similar to that of the first embodiment. However, in the third embodiment, the first positioning members 61 are disposed in an equangularly spaced-apart manner on the connecting ring inner surface 51 of the connecting ring 5. The second positioning members 62 are disposed in an equiangularly manner on the polishing ring outer surface 42 of the polishing ring 4.

Each of the first positioning members 61 is integrally formed on the connecting ring 5 and extends radially and inwardly from the connecting ring installation portion 513 of the connecting ring inner surface 51.

Each of the second positioning members 62 is indented from the polishing ring installation portion 421 of the polishing ring outer surface 42 and is integrally formed on the polishing ring 4. The sliding slot portion 63 of each of the second positioning members 62 is indented from the polishing ring installation portion 421 of the polishing ring outer surface 42 and extends circumferentially along the polishing ring outer surface 42. The entry slot portion 64 of each of the second positioning members 62 is indented from the polishing ring installation portion 421 of the polishing ring outer surface 42, is in communication with the sliding slot portion 63, and extends through the polishing ring top surface 43.

In the third embodiment, the polishing ring 4 is made of an engineering plastic such as, but not limited to, polyphenylene sulfide (PPS) and polyether ether ketone (PEEK). The connecting ring 5 and the first positioning members 61 are made in one piece of a metal material such as, but not limited to, stainless steel.

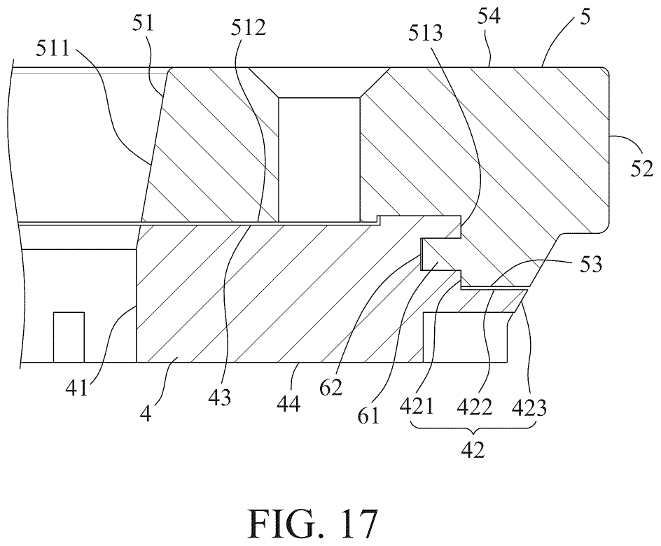

Referring to FIGS. 13, 16, and 17, to assemble the wafer positioning ring device of the disclosure, the first positioning members 61 are first abutted against the polishing ring top surface 43. Sequentially, the connecting ring is slightly rotated relative to the polishing ring 4 and is pushed toward the polishing ring 4. When the first positioning members 61 are respectively moved above the second positioning members 62, each of the first positioning members 61 is allowed to be inserted into the sliding slot portion 63 through the entry slot portion 64 of the respective one of the second positioning members 62.

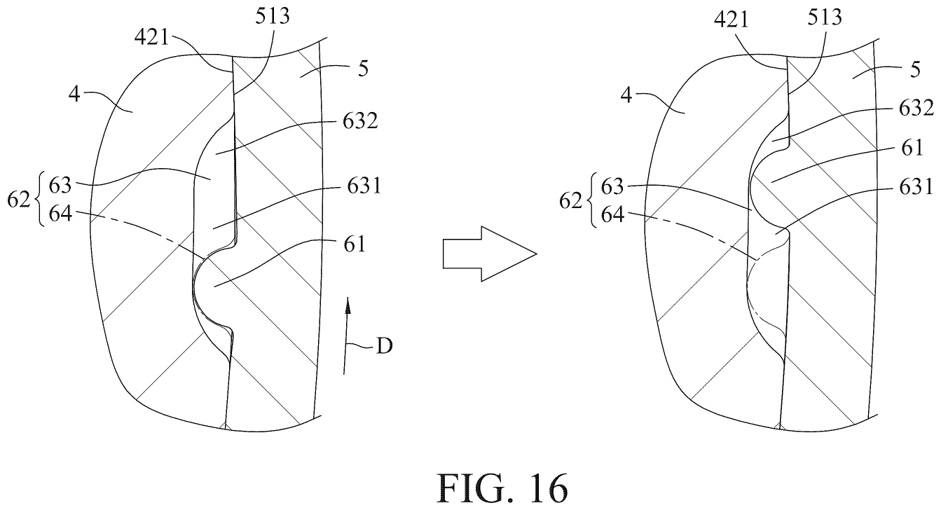

Referring to FIG. 16, the connecting ring 5 is rotated relative to the polishing ring 4 along the rotational direction (D) such that each of the first positioning members 61 is inserted into the restricting region 632 from the sliding region 631 of the sliding slot portion 63 of the respective one of the second positioning members 62. As a result, the first positioning members 61 are respectively positioned and connected to the second positioning members 62 such that the connecting ring 5 is positioned on the top of the polishing ring 4.

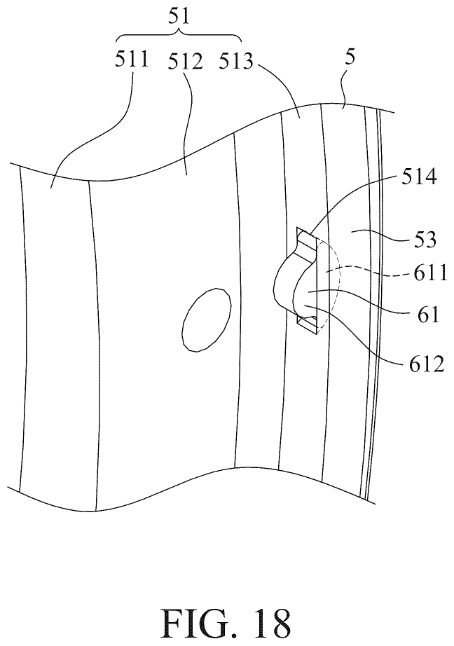

FIG. 18 illustrates a wafer positioning device according to a fourth embodiment of the disclosure, which has a structure substantially similar to that of the third embodiment. However, the first positioning members 61 are not integrally formed on the connecting ring 5.

In the fourth embodiment, the connecting ring inner surface 51 has a plurality of installing recesses 514 that are indented from the connecting ring installation portion 513 and that are equianuglarly spaced-apart from each other. Each of the first positioning members 61 has an arcuate installation segment 611 and an engagement segment 612 that projects outwardly and is arcuately tapered from the arcuate installation segment 611. The arcuate installation segments 611 of the first positioning members 61 engage respectively with the installing recesses 514. The engagement segments 612 of the first positioning members 61 are allowed to engage with the second positioning members 62, respectively.

To assemble the wafer positioning ring device of the disclosure, the first positioning members 61 are first respectively engaged with the installing recesses 514 of the connecting ring inner surface 51 such that the connecting ring abuts against the top of the polishing ring 4. Sequentially, the connecting ring 5 is positioned on the top of the polishing ring 4 in the manner described in the third embodiment

In summary, because the first positioning members 61 are spaced apart from each other and are disposed on one of the polishing ring outer surface 42 of the polishing ring 4 and the connecting ring inner surface 51 of the connecting ring 5, and because the second positioning members 62 are spaced apart from each other and are disposed on another one of the polishing ring outer surface 42 of the polishing ring 4 and the connecting ring inner surface 51 of the connecting ring 5, by rotating the connecting ring 5 relative to the polishing ring 4, the second positioning members 62 and the first positioning members 61 are detachably and respectively connected to each other such that the connecting ring 5 is positioned on the top of the polishing ring 4, thereby increasing assembling efficiency.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A wafer positioning ring device comprising:
a polishing ring having a polishing ring inner surface and a polishing ring outer surface that surrounds said polishing ring inner surface;
a connecting ring having a connecting ring inner surface and a connecting ring outer surface that surrounds said connecting ring inner surface; and
a positioning unit including
a plurality of first positioning members that are spaced apart from each other and that are disposed on one of said polishing ring outer surface of said polishing ring and said connecting ring inner surface of said connecting ring, and
a plurality of second positioning members that are spaced apart from each other and that are disposed on another one of said polishing ring outer surface of said polishing ring and said connecting ring inner surface of said connecting ring;
wherein said plurality of second positioning members and said plurality of first positioning members are detachably and respectively connected to each other such that said connecting ring is positioned on top of said polishing ring.

2. The wafer positioning ring device as claimed in claim 1, wherein each of said plurality of first positioning members is a protrusion, and each of said plurality of second positioning members is a slot.

3. The wafer positioning ring device as claimed in claim 2, wherein:
each of said plurality of first positioning members is integrally formed on said polishing ring and extends radially and outwardly from said polishing ring outer surface; and
each of said plurality of second positioning members is indented from said connecting ring inner surface.

4. The wafer positioning ring device as claimed in claim 3, wherein:
said connecting ring further has a connecting ring bottom surface that faces downwardly and that interconnects said connecting ring inner surface and said connecting ring outer surface; and
each of said plurality of second positioning members has
a sliding slot portion that is indented from said connecting ring inner surface and that extends circumferentially along said connecting ring inner surface, and
an entry slot portion that is indented from said connecting ring inner surface, that is in communication with said sliding slot portion, and that extends through said connecting ring bottom surface.

5. The wafer positioning ring device as claimed in claim 4, wherein said sliding slot portion of each of said plurality of second positioning members has
a sliding region that is aligned with said entry slot portion and that allows a respective one of said plurality of first positioning members to be inserted therein, and
a restricting region that is in communication with said sliding region, that is not aligned with said entry slot portion, and that retains said respective one of said plurality of first positioning members when said connecting ring is rotated relative to said polishing ring after said respective one of said plurality of first positioning members is inserted into said sliding region, thereby positioning said connecting ring on said top of said polishing ring.

6. The wafer positioning ring device as claimed in claim 2, wherein:
said polishing ring outer surface has a plurality of installing recesses;
said plurality of first positioning members engage respectively with said plurality of installing recesses; and
each of said plurality of second positioning members is indented from said connecting ring inner surface.

7. The wafer positioning ring device as claimed in claim 6, wherein:
said connecting ring further has a connecting ring bottom surface that faces downwardly and that interconnects said connecting ring inner surface and said connecting ring outer surface; and
each of said plurality of second positioning members has
a sliding slot portion that is indented from said connecting ring inner surface and that extends circumferentially along said connecting ring inner surface, and
an entry slot portion that is indented from said connecting ring inner surface, that is in communication with said sliding slot portion, and that extends through said connecting ring bottom surface.

8. The wafer positioning ring device as claimed in claim 7, wherein said sliding slot portion of each of said plurality of second positioning members has
a sliding region that is aligned with said entry slot portion and that allows a respective one of said plurality of first positioning members to be inserted therein, and
a restricting region that is in communication with said sliding region, that is not aligned with said entry slot portion, and that retains said respective one of said plurality of first positioning members when said connecting ring is rotated relative to said polishing ring after said respective one of said first positioning members is inserted into said sliding region, thereby positioning said connecting ring on said top of said polishing ring.

9. The wafer positioning ring device as claimed in claim 2, wherein:
each of said plurality of second positioning members is indented from said polishing ring outer surface; and
each of said plurality of first positioning members is integrally formed on said connecting ring and extends radially and inwardly from said connecting ring inner surface.

10. The wafer positioning device as claimed in claim 9, wherein:
said polishing ring further has a polishing ring top surface that faces upwardly and that interconnects said polishing ring inner surface and said polishing ring outer surface; and
each of said plurality of second positioning members has
a sliding slot portion that is indented from said polishing ring outer surface and that extends circumferentially along said polishing ring outer surface, and
an entry slot portion that is indented from said polishing ring outer surface, that is in communication with said sliding slot portion, and that extends through said polishing ring top surface.

11. The wafer positioning ring device as claimed in claim 2, wherein:
each of said plurality of second positioning members is indented from said polishing ring outer surface;
said connecting ring inner surface has a plurality of installing recesses; and
said plurality of first positioning members engage respectively with said plurality of installing recesses.

12. The wafer positioning device as claimed in claim 11, wherein:
said polishing ring further has a polishing ring top surface that faces upwardly and that interconnects said polishing ring inner surface and said polishing ring outer surface; and
each of said second positioning members has
a sliding slot portion that is indented from said polishing ring outer surface and that extends circumferentially along said polishing ring outer surface, and
an entry slot portion that is indented from said polishing ring outer surface, that is in communication with said sliding slot portion, and that extends through said polishing ring top surface.

13. The wafer positioning ring device as claimed in claim 2, wherein each of said plurality of first positioning members is a semi-circular protrusion.
